(19) United States
(12) Patent Application Publication
(10) Pub. No.: US 2024/0367214 A1
(43) Pub. Date: Nov. 7, 2024

(54) FLATTENING AND SMOOTHING METALLIC WAFERS AND PLATES FOR FLEXIBLE ELECTRONICS

(71) Applicant: The Research Foundation for the State University of New York, Albany, NY (US)

(72) Inventors: Haralabos Efstathiadis, Albany, NY (US); Iulian Gherasoiu, Utica, NY (US); Yamini Kumaran, Albany, NY (US)

(21) Appl. No.: 18/654,117

(22) Filed: May 3, 2024

Related U.S. Application Data
(60) Provisional application No. 63/463,692, filed on May 3, 2023.

(51) Int. Cl. B21D 39/03

(52) U.S. Cl. CPC B21D 39/03

(57) ABSTRACT

A system and method for producing a flattened and smoothed metallic wafer using a top pressure tool plate and a bottom pressure tool plate with a first pressure application device in physical contact with the top pressure tool plate and a second pressure application device in physical contact with the bottom pressure tool plate. A first semiconductor wafer in is selective contact with the top pressure tool plate and a second semiconductor wafer is in selective contact with the bottom pressure tool plate, with a metallic wafer held between the first semiconductor wafer and second semiconductor wafer. The first and second semiconductor wafers can be Si wafers. A predetermined amount of pressure is applied for a predetermined duration from the top pressure tool plate and bottom pressure tool plate with the first pressure application device and second pressure application device to flatten and smooth the metallic wafer.

### CROSS-REFERENCE TO RELATED APPLICATION

This application claims the benefit of U.S. Provisional Patent Application No. 63/463,692, filed May 3, 2023, the entirety of which is hereby incorporated herein by this reference.

### BACKGROUND OF THE INVENTION

### 1. Field of the Invention

The present invention generally relates to semiconductors and methods of their fabrication. More particularly, the present invention relates to a system and method for flattening and smoothing metal wafer and plates as components of flexible electronic devices.

### 2. Description of the Related Art

The creation of electronic devices on flexible substrates is an emerging technology that has gained considerable attention in recent years due to its potential applications in wearable devices, biomedical sensors, and with other flexible electronic devices. A key challenge in the development of flexible electronics is the selection of suitable substrates that can withstand mechanical stress caused by bending and stretching without detrimentally affecting the electronic components of the substrate. The specific flexible materials are typically electric conductive or ionic conductive made from carbon-based materials, conductive polymers, and metal and metal oxide sheets (or foils).

Metal substrates have emerged as a promising alternative to conventional polymer substrates due to their high thermal conductivity, good electrical conductivity, and excellent mechanical properties. Various metals such as copper, aluminum, stainless steel, molybdenum, and titanium have been investigated for use as flexible electronic substrates.

In current methods to create an electronic structure flexible, two major approaches are commonly employed: 1) Transfer and bonding of completed circuits to flexible circuits; and 2) Fabrication of the circuits directly on the flexible substrates. The transfer and bond approach has a main drawback of its small surface area coverage and high cost, although it can provide high-performance devices.

Direct fabrication of flexible electronics is more common where the electronic devices are fabricated directly on a flexible substrate. However, this method of manufacture is not compatible with existing planar silicon microfabrication processes. Further, direct fabrication often relies on polycrystalline or amorphous semiconductors grown on foreign substrates, but these process techniques make tradeoffs between device performance and low process temperatures.

With respect to metal substrates, there have been several studies that have investigated fabricating and characterizing materials grown on metal-based substrates for flexible electronics. One such study explored the possibility of using Mo metal foils to grow GaAs by MOCVD achieving cost reduction, flexibility, and high specific and areal power densities for III-V-based solar cells. Metal substrates also help in the deposition of 2D materials like MoS₂ by reducing the growth temperature and ease of producing metal semiconductor contacts without film transfer. Additionally, there are studies into thin-film silicon electronics where metal wafers can be used as the substrate for the growth of polycrystalline SiO₂ films for fabrication and integration. Additionally, various techniques have been developed to make these metals more ductile and resilient, including annealing, cold-rolling, and electroplating.

However, existing methods of using metal substrates to manufacture flexible electronics create devices that are still subject to the damage problems common from the substrate being flexible. Bending and flexing to relatively small curvatures is a key feature of flexible electronics, but these actions expose the circuitry to fatigue damage. Further, the conductivity of the metal substrate can create further problems if layers of the device separate and allow current leakage between the devices.

The production of metal substrates for flexible electronics initially starts with the formation of a cylindrical ingot or billet using crystallization, solid state, or other ultra-high purification processes such as sublimation. Further, the ingot is processed through several steps such as hot rolling, punching, coarse grinding, annealing, machining, and surface treatment. However, due to the deformation of the metal wafer during the punching process, it typically has a concave top and a convex shape with the periphery appearing radial, producing a significant bow and warp to them making it difficult for further usage in the fabrication of flexible electronic devices. Therefore, it is preferable to make sure the metal wafers have appropriate flatness, in a manner similar to conventional silicon wafers which are currently used as the substrate for integrated circuits.

Overall, metal substrates remain a promising option for flexible electronics due to their excellent mechanical and thermal properties, and ongoing research is focused on further improving their flexibility, stretchability, flatness, and adhesion to other materials. It is thus to the fabrication and use of flexible electronics on metallic substrates that the present invention is primarily directed.

### BRIEF SUMMARY OF THE INVENTION

Briefly described, the present invention provides a system and method for producing flattened and smoothed metallic wafers that are advantageous for use in flexible electronics. The system for producing a metallic wafer substrate includes a top pressure tool plate, a bottom pressure tool plate, a first pressure application device in physical contact with the top pressure tool plate, and a second pressure application device in physical contact with the bottom pressure tool plate. There is a first semiconductor wafer in selective contact with the top pressure tool plate, a second semiconductor wafer in selective contact with the bottom pressure tool plate, and a metallic wafer selectively held between the first semiconductor wafer and second semiconductor wafer. A predetermined amount of pressure is applied, for a predetermined duration, to the top pressure tool plate and bottom pressure tool plate respectively by the first pressure application device and second pressure application device, thereby further applying pressure to the first semiconductor wafer and second semiconductor water respectively to thereby flatten and smooth the metallic wafer.

The system can further include a heating device that selectively applies a predetermined temperature to the system. In one embodiment, the first semiconductor wafer and second semiconductor wafer can include Si. Further, the layer comprising the metallic wafer can be deposited on the first semiconductor wafer, and the second semiconductor wafer is deposited on the metallic wafer, and there can be a SiO₂ layer on the metallic wafer.

The predetermined duration of pressure can reduce the roughness on the metallic wafer to a predetermined level. The metallic wafer can be comprised of one or more of the group of: Mo, W, Cu, Al, and Ti. Further, the predetermined temperature can be in a range of 150° C. to 250° C.

In one embodiment, the invention also includes a method for producing a flattened metallic wafer substrate that starts with placing a second semiconductor wafer on a bottom pressure tool plate, the bottom pressure tool plate in physical contact with a second pressure application device, then placing a metallic wafer on the second semiconductor wafer, and placing a first semiconductor wafer on the metallic wafer, the first semiconductor wafer in physical contact with a top pressure tool plate, and the top pressure tool plate in physical contact with a first pressure application device. The method continues with applying a predetermined amount of pressure for a predetermined duration on the metallic wafer from the top pressure tool plate and bottom pressure tool plate respectively from the first pressure application device and second pressure application device, thereby further applying pressure to the first semiconductor wafer and second semiconductor water, respectively, and flattening and/or smoothing the metallic wafer.

The method can include heating, at least, the metallic wafer, which can occur within a predetermined range of temperature between 150° C. to 250° C. The predetermined amount of pressure can be between 1500 psi to 2000 psi. The step of placing the metallic wafer can be depositing the metallic wafer on the second semiconductor wafer.

The method can further include depositing a SiO₂ layer on the metallic wafer. The method can also include reducing roughness on the metallic wafer to a predetermined level, with the reducing roughness occurring from the predetermined duration of pressure. This is effectively smoothing the metal wafer. Further, applying a predetermined amount of pressure for a predetermined duration can be applying the predetermined amount of pressure in a duration between 30 minutes to 60 minutes.

In sum, the present invention includes a hot press of metal wafers sandwiched between silicon wafers, which not only improves the flatness but also decreases the surface roughness of the wafers. The invention includes the use of silicon wafers, which have ultra smooth surface that greatly assists in the flattening and smoothing. Further, the eutectic point of silicon with most refractory metals (Mo, W, Ta) lies at high temperatures of 1000° C. or greater. Thus, during the hot press, the formation of alloys while pressing at lower temperatures is negligible. The flattening time, temperature and pressure are optimized to achieve wafer quality to silicon standards. The present approach therefore provides a facile way of improving the metallic wafer's quality by eliminating the number of process steps and, hence, the cost of metal wafer production for flexible electronic applications.

The present invention therefore provides an advantage in the smoothening and flattening of metallic wafers for use in flexible electronics. Further, the present invention has industrial applicability in the production of semiconductor devices, and in particular, metallic substrates for use in flexible electronics. Other objects, advantages, and features of the present application will be apparent to one of skill of the art after review of the present application.

### BRIEF DESCRIPTION OF THE DRAWINGS

FIG. 1 is a diagram of one embodiment of the system for providing a flattened and smoothed metallic wafer.

FIG. 2 is a table of the parameters of experimental metallic wafers produced by the system in FIG. 1.

FIG. 3 is a table of the average bowing of the experimental metallic wafers produced in FIG. 2.

FIG. 4 is a table of additional metallic wafers produced after flattening and smoothing by the system of FIG. 1.

FIG. 5 is a table illustrating average bowing with the use of an SiO₂ layer on the metallic wafer.

FIG. 6 is a picture illustrating the deposition of an SiO₂ layer on the metallic wafer.

FIG. 7 is a table of the comparison of surface roughness of the wafers produced by the parameters in FIG. 2.

FIG. 8A is a graph with data parameters of the roughness for sample MOW_3B in FIG. 2.

FIG. 8B is a graph of the surface roughness of the sample MOW_3B in FIG. 8A.

FIG. 9A is a graph with data parameters of the roughness of sample MOW_5A in FIG. 2.

FIG. 9B is a graph of the surface roughness of the sample MOW_5A in FIG. 9A.

FIG. 10 is a table of additional test samples and pressures and times, illustrating the control and reduction of bowing in metal wafers.

FIG. 11 is a graph indicating the reduction of bowing as measured by wafer orientation.

FIG. 12 is a graph of flipping the metal wafer during pressing to further reduce bowing.

FIG. 13 is a graph of several samples of metal wafers with various levels of metal oxide formed from the hot press process.

FIG. 14 is a graph illustrating the oxide growth on both sides of a metal wafers based upon temperature used.

FIG. 15 is a table of further sample MOW waters with roughness elliptically measured for various temperatures, pressures and times of pressing.

FIG. 16A is a graph of the effect of bow average from the change in temperature during the pressing process for a sample metal wafer.

FIG. 16B is a graph of the effect of time (duration) on the bow average for a sample wafer.

### DETAILED DESCRIPTION OF THE INVENTION

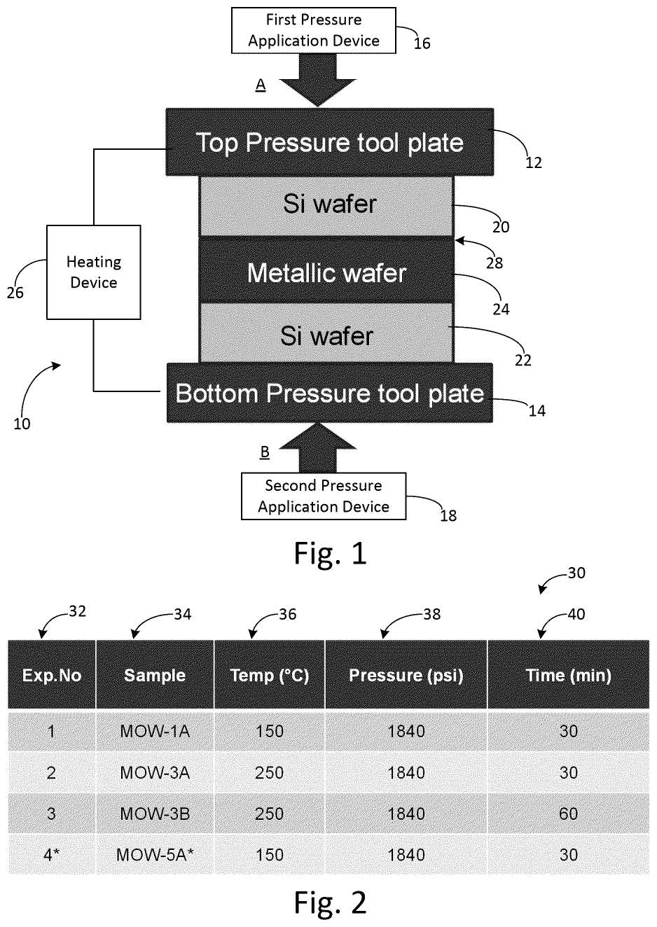

With reference to the figures in which like numerals represent like elements throughout the several views, FIG. 1 a diagram of one embodiment of the system 10 for providing a flattened and smoothed metallic wafer 24. The present innovation of the flattening of metallic wafers 24 lies on the insertion of first semiconductor wafer 20 and second semiconductor wafer 22, which are preferably Si, used for microelectronic applications, on both sides of the a metallic wafer 24, between the plates of the pressure tool and metallic wafer 24 in order to both smooth the surface of the metallic wafer 24 and flatten it by applying pressure and heat.

The production of the metal wafer 24, which can be a substrate, initially starts with the formation of cylindrical ingot or billet using crystallization, solid state, or other ultra-high purification processes such as sublimation, as known in the art. Further, the ingot is processed through several known steps such as hot rolling, punching, coarse grinding, annealing, machining, and surface treatment. However, due to the deformation of the metal wafer 24 during the common punching process step, it will have a concave top and a convex shape with the periphery appearing radial, producing a significant bow and warp. This warping makes it difficult for further usage in the fabrication of electronic devices. Therefore, it is necessary to make sure the metal wafer 24 has an appropriate flatness like the conventional silicon wafers which are currently used as the substrate for integrated circuits.

Existing methods like hot/cold repressing, laser forming, leveling, and grinding, that are followed by annealing are currently used to flatten the metallic wafer substrates. The flattened substrates have been followed by re-polishing of the substrates, which can actually increase the surface roughness. The surface roughness is an important parameter to be considered for overall wafer quality. Hence, it is desirous to decrease both surface roughness and the warpage of the metal wafer 24 at lower processing steps and cost.

FIG. 1 is a diagram of one embodiment of the system 10 for providing a flattened and smoothed metallic wafer 24. The system 10 includes a top pressure tool plate 12, a bottom pressure tool plate 14, a first pressure application device 16 in physical contact with the top pressure tool plate 12, and a second pressure application device 18 in physical contact with the bottom pressure tool plate 14. There is a first semiconductor wafer 20 in selective contact with the top pressure tool plate 12, a second semiconductor wafer 22 in selective contact with the bottom pressure tool plate 14, and a metallic wafer 24 is selectively held between the first semiconductor wafer 20 and second semiconductor wafer 22.

A predetermined amount of pressure is applied, for a predetermined duration, to the top pressure tool plate 12 and bottom pressure tool plate 14 respectively from the first pressure application device 12 (direction of arrow A) and second pressure application device 18 (direction of arrow B), thereby further applying pressure to the first semiconductor wafer 20 and second semiconductor water 22 respectively, to thereby flatten and smooth the metallic wafer 24. The system 10 can further include a heating device 26. The heating device 26 selectively applies a predetermined temperature to the system 10, and specifically the metallic wafer 24, which can be in a range of 150° C. to 400° C. Greater temperatures up to 1000° C. are also potentially possible depending upon the substrates utilizes, as well as the atmospheric condition used.

The first semiconductor wafer 20 and second semiconductor wafer 22 can include pure Si, but can be partially Si, or like substance to perform the flattening and smoothing function described herein. Alternate semiconductor wafers can be constructed from LaAlO₃ or sapphire. Further, the metallic wafer 24 can be deposited on the second semiconductor wafer 22, and the first semiconductor wafer 20 can be deposited on the metallic wafer 24.

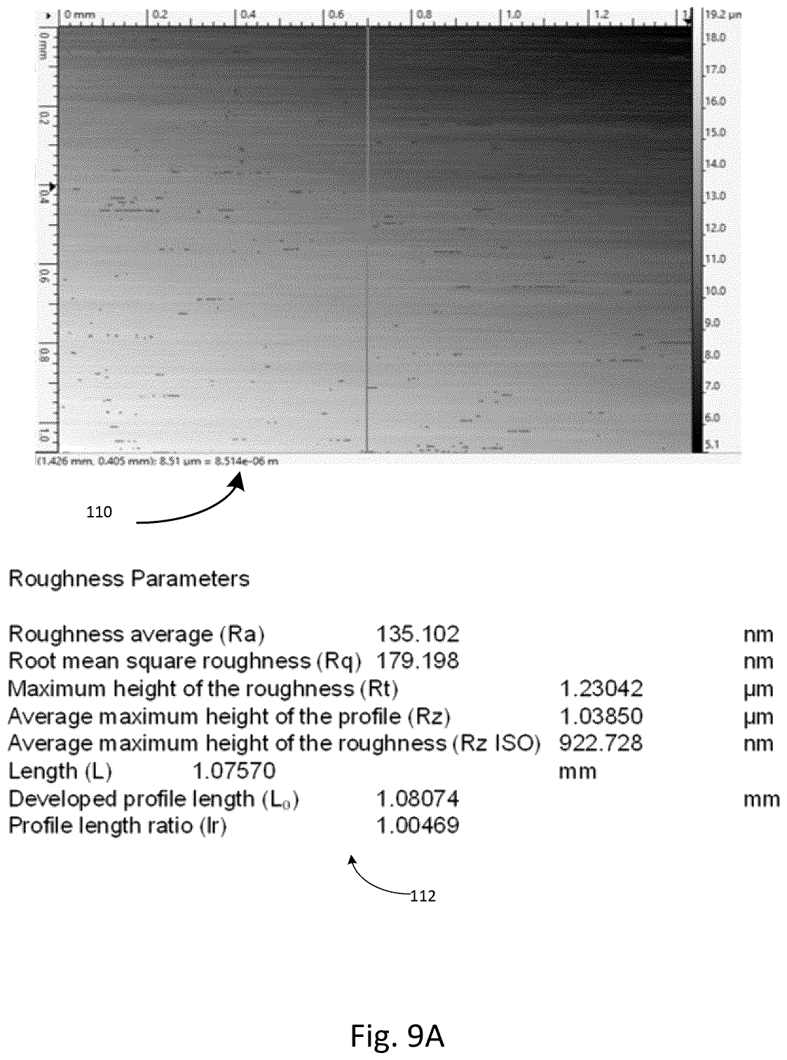

Additionally, there can be an SiO₂ layer 28 on the top or bottom of the metallic wafer 24 to affect the properties of the process as desired. The predetermined duration of pressure will reduce roughness on the metallic wafer to a predetermined level, as is shown in FIGS. 7-9A. Further, the metallic wafer 24 can be comprised of one or more of the group of: Mo, W, Cu, Al, and Ti. Other metallic materials can also be used either in pure form or alloy in creating the metallic wafer 24.

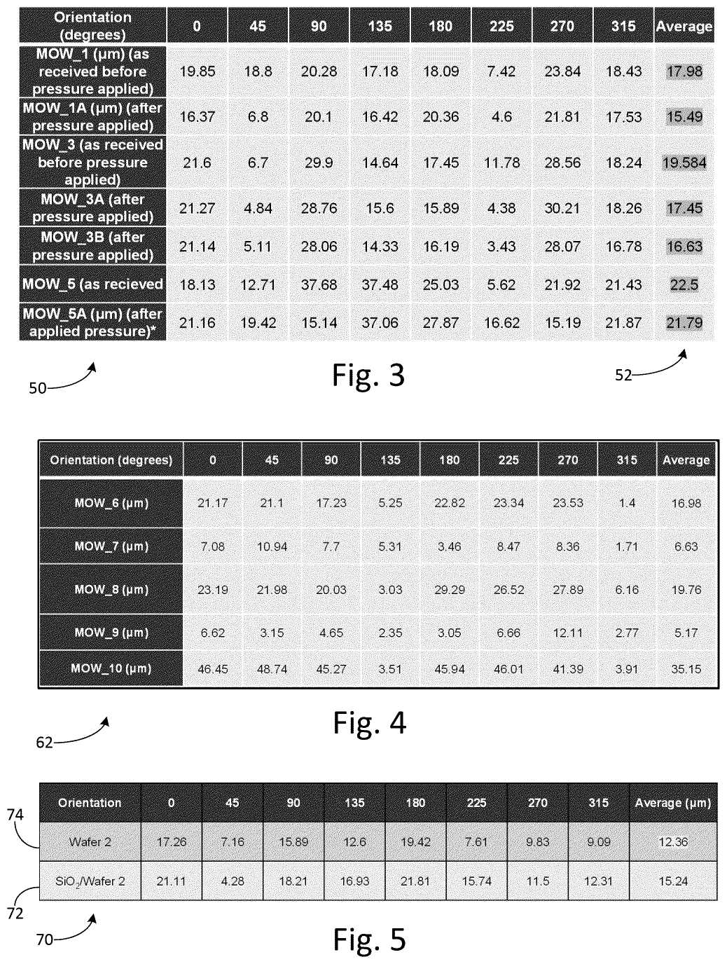

FIG. 2 is a table 30 of the parameters of experimental metallic wafers produced by the system 10 in FIG. 1. The experiments column 32 is next to the samples column 34 to identify the wafer sample tested. For each experiment, the temperature (column 36, the pressure used (column 38), and the duration of exposure (column 40) are shown. Note for the pressure calculation: Clamping force—10 tons; Area—12.1736 inch² (area of wafer); tons/inch²—0.814; tons/inch² to psi—1840 psi.

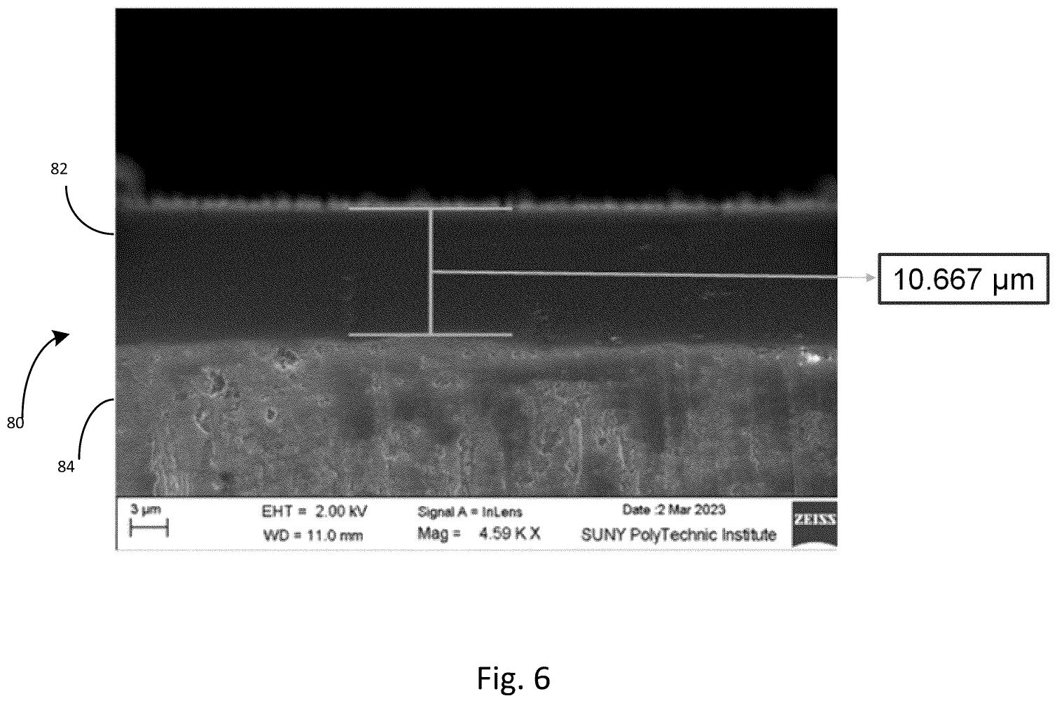

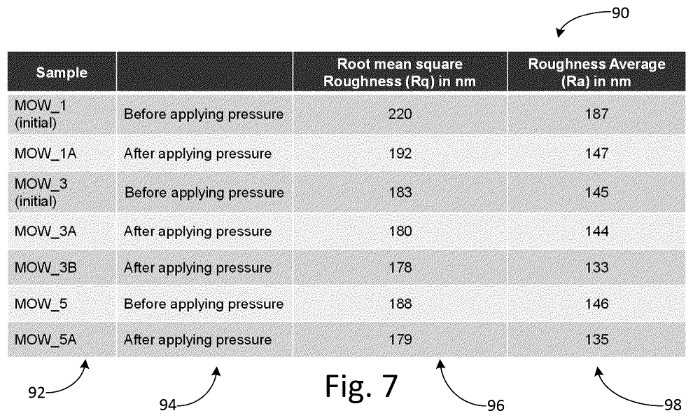

FIG. 3 is a table 50 of the average bowing of the experimental metallic wafers produced in FIG. 2 when Si is used as the first semiconductor wafer 20 and second semiconductor wafer 22, configured according to the system in FIG. 1. The average bowing column 52 demonstrates the effect of pressure on a bowed metallic wafer 24. FIG. 4 is a table 60 of additional Mo metallic wafers produced after flattening and smoothing by the system of FIG. 1. The table 60 shows the reduction in bowing from the hot press.

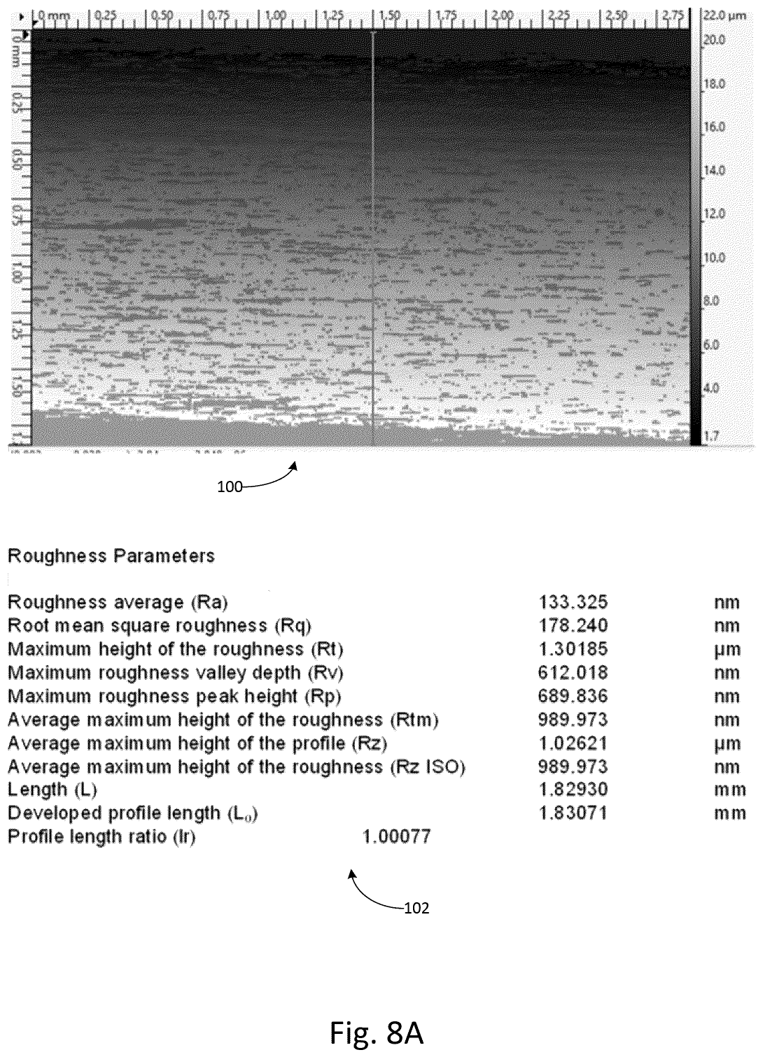

FIG. 5 is a table 70 illustrating average bowing with the use of an SiO₂ layer 28 (row 72) on the metallic wafer 24. A control metallic wafer (column 74) without an SiO₂ layer is also shown for comparison. While slight additional bowing occurred with the SiO₂ layer 28, the advantageous properties can still be had without significant adverse bowing of the metal wafer 24.

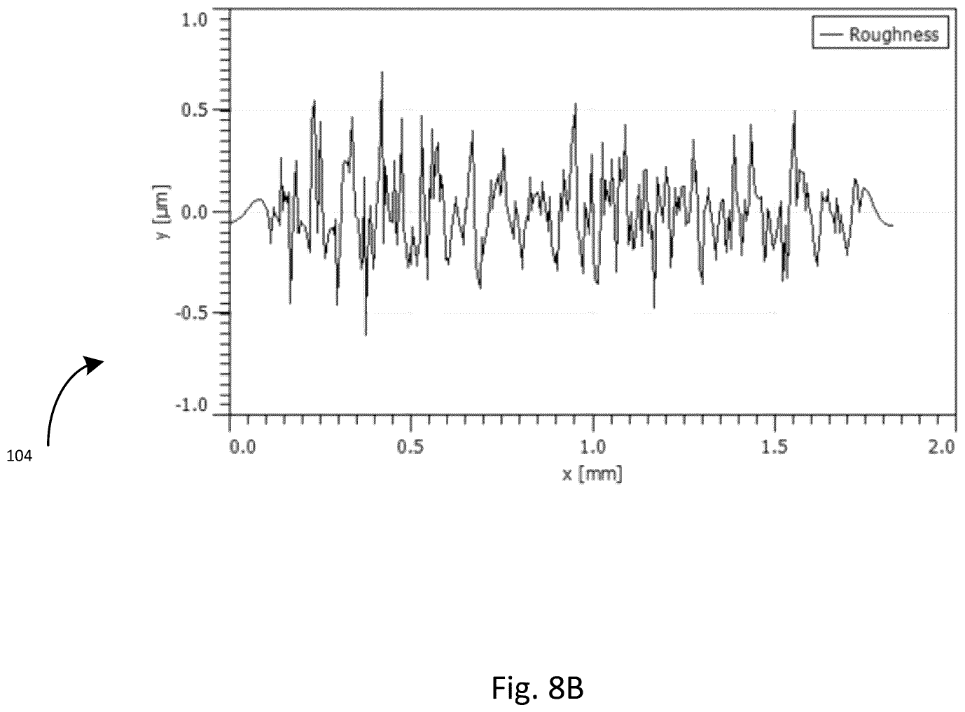

FIG. 6 is a picture 80 illustrating the deposition of an SiO₂ layer 82 on the metallic wafer 84. The SiO₂ layer 82 here is shown as 10.667 μm thick, but this is simply an embodiment of the layer and not a limitation. The system 10 in FIG. 1 can be used to produce the metallic wafer in the picture 80.

FIG. 7 is a table 90 of the comparison of surface roughness of the wafers produced by the parameters in FIG. 2. The sample column 92 shows the samples before and after applying pressure (column 94). The means square roughness for the samples is shown in column 96 with the average roughness shown in column 98. The roughness is shown in spot sample per nm, with the average of the samples in column 98.

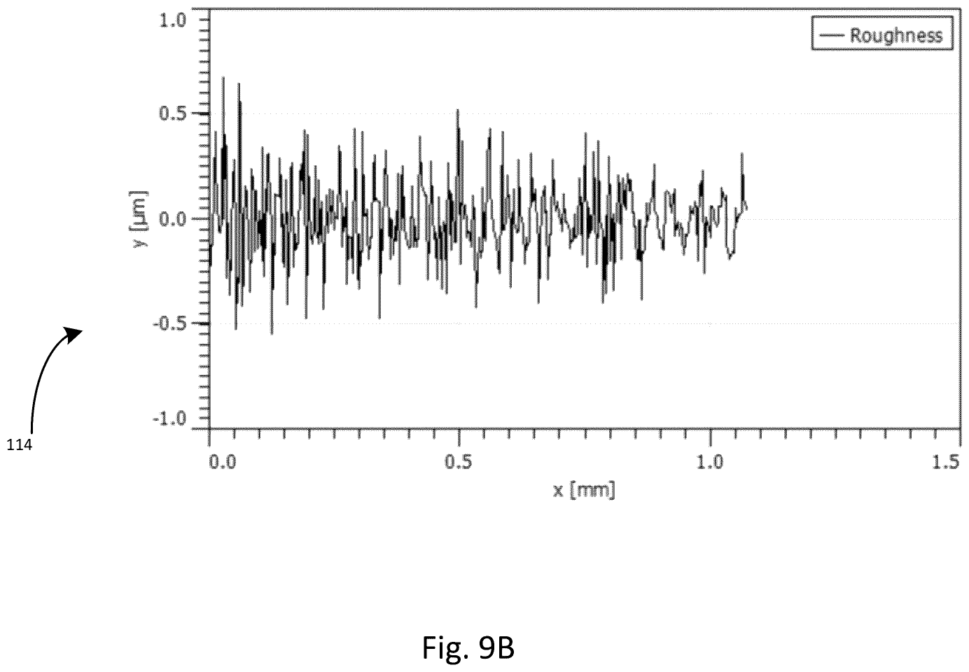

FIG. 8A is a graph-plot 100 with data 102 of the roughness for sample MOW_3B in FIG. 2. The graph plot 100 and data 102 are for the average roughness over the surface of the MOW/3B sample. FIG. 8B is a graph 104 of the surface roughness of the sample MOW_3B in FIG. 8A.

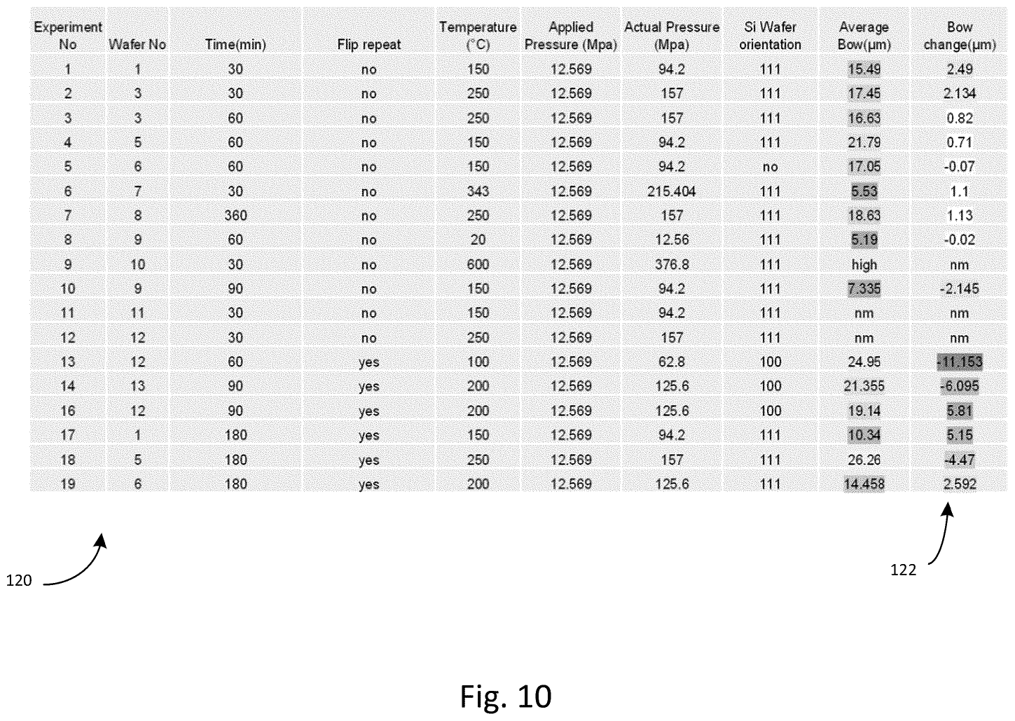

FIG. 9A is a graph 110 with data 112 of the roughness of sample MOW_5A in FIG. 2. FIG. 9B is a graph 114 of the surface roughness of the sample MOW_5A in FIG. 9A.

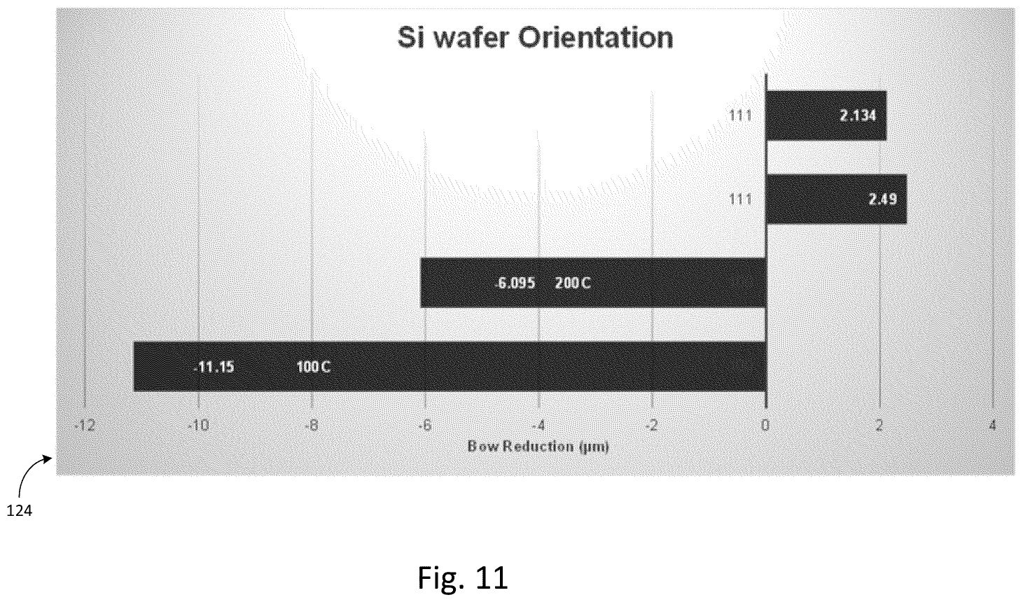

FIG. 10 is a table 120 of additional test samples and pressures and times, illustrating the control and reduction of bowing in metal wafers. The bow change is illustrated in column 122, which demonstrates the intentional affect of bowing of the metal wafer 24 under varying temperatures (0° C.), pressures (Mpa), and times.

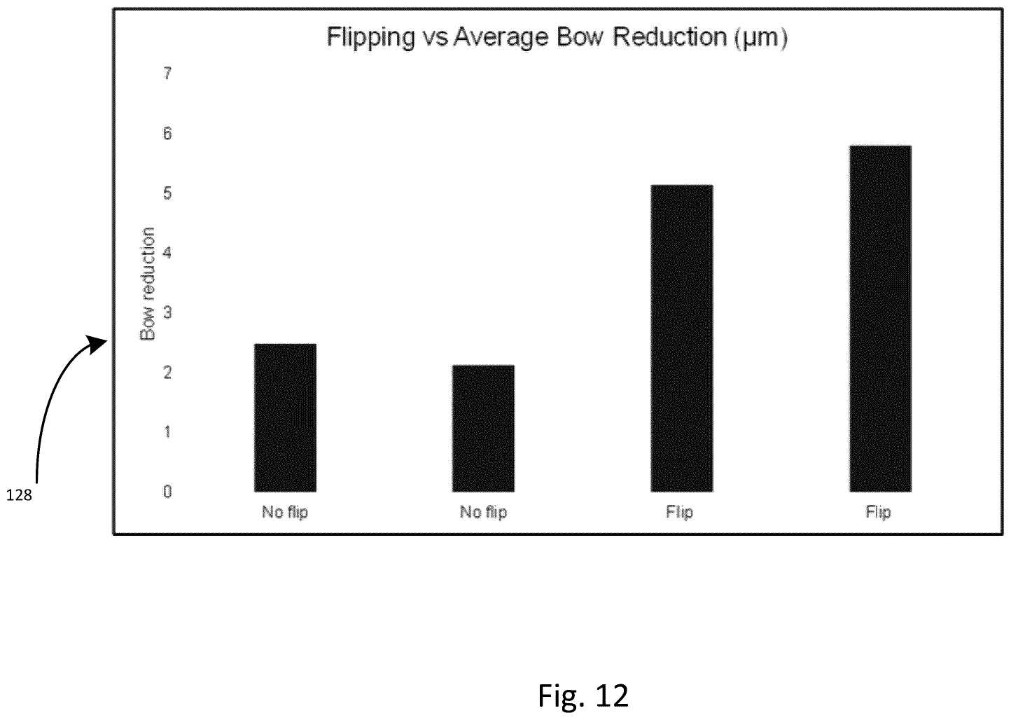

FIG. 11 is a graph 124 indicating the reduction of bowing as measured by wafer orientation. The graph 124 demonstration the percentage reduction in bowing as against the heat of the press used, versus the untreated wafers.

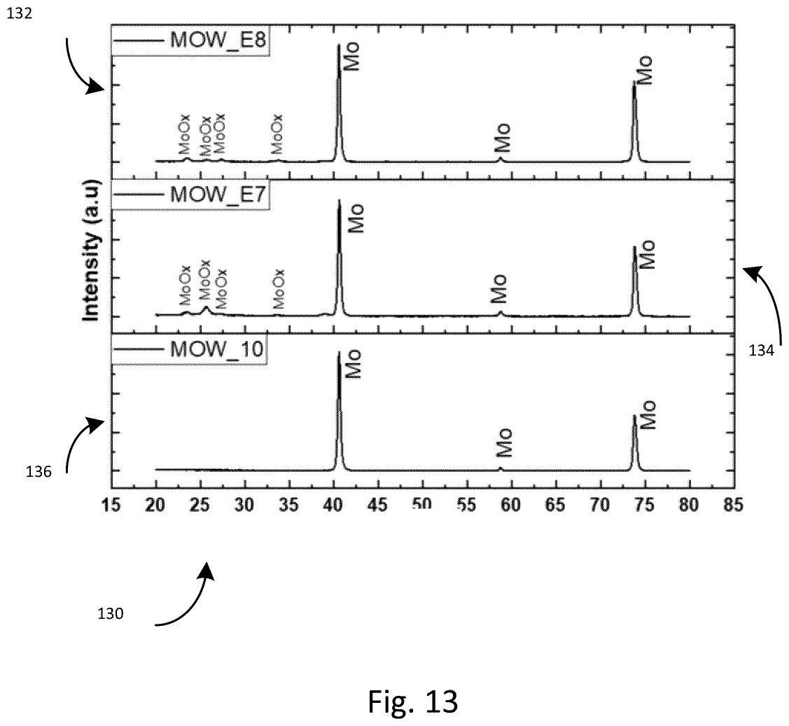

FIG. 12 is a graph 128 of flipping the metal wafer during pressing to further reduce bowing. The metal wafer 24 can accordingly be flipped between the first semiconductor wafer 20 and second semiconductor wafer 22 to significantly reduce bowing, as shown herein μm of reduction.

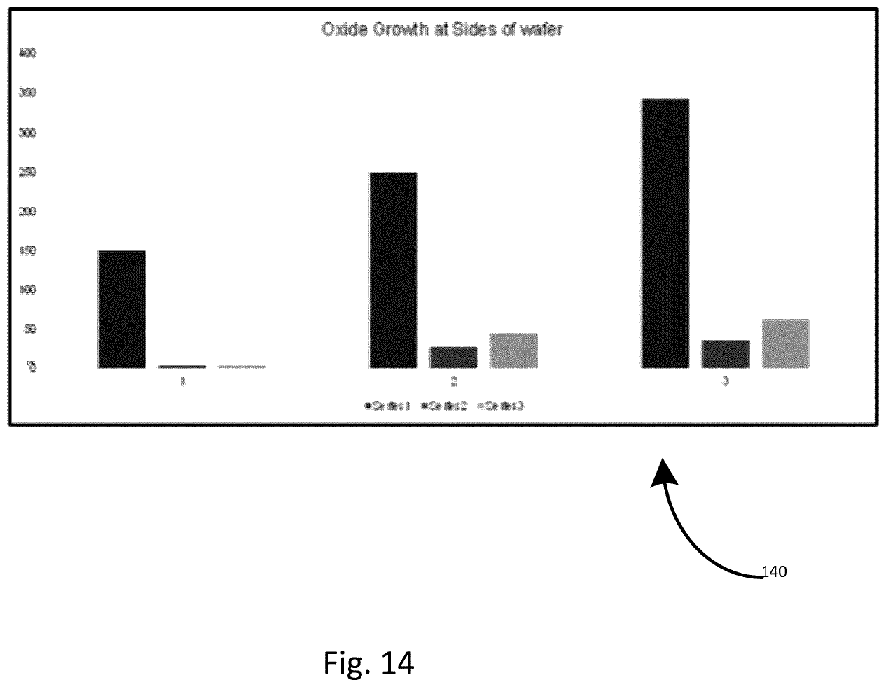

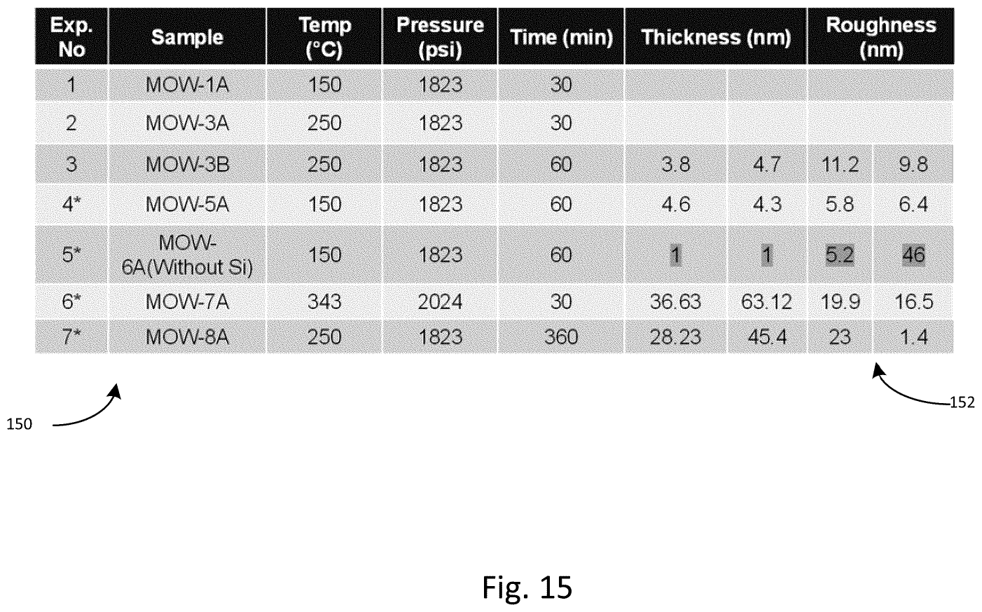

FIG. 13 is a graph 130 of several samples of metal wafers with various levels of metal oxide formed from the hot press process. The system 10 and method described herein can be performed in ambient air, under a vacuum, devoid of O₂, or with inert gases like Ar, N, Kr, He, Xe or Ne. If oxygen is present during the process, metal oxides will form on the metal wafer 24. For example, in graph 130, for sample MOW_E8 (row 132), and MOW_E7 (row 134), show the oxides forming on the Mo wafer. Lower temperature will reduce or eliminate metal oxides, as shown at row 136. The amount of metal oxide can be controlled as is shown in FIG. 14.

FIG. 14 is a graph 140 illustrating the oxide growth on both sides of a metal wafers based upon temperature used. Thus, the metal wafer 24 can be flipped after an initial pressing, and the method to flatten and smooth the metal wafer 24 would include the step of flipping the metal wafer 24 between the first semiconductor wafer 20 and second semiconductor 22 and a second step of applying pressure will occur.

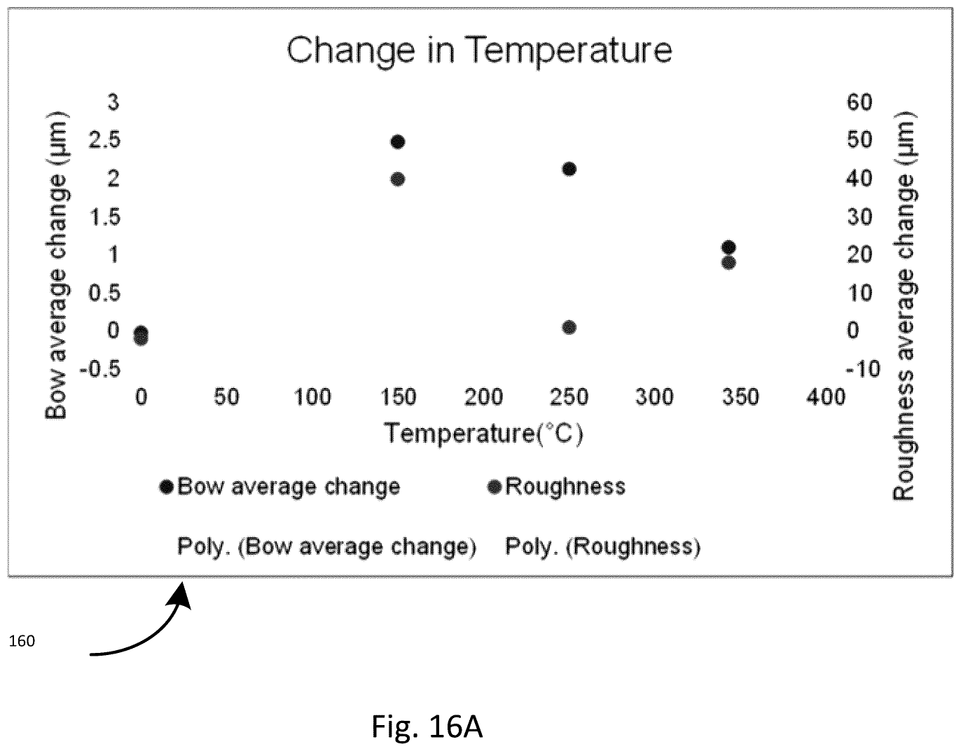

FIG. 15 is a table 150 of further sample MOW waters with roughness elliptically measured for various temperatures, pressures and times of pressing. Roughness is shown as a measure of smoothness per nm, in row 152.

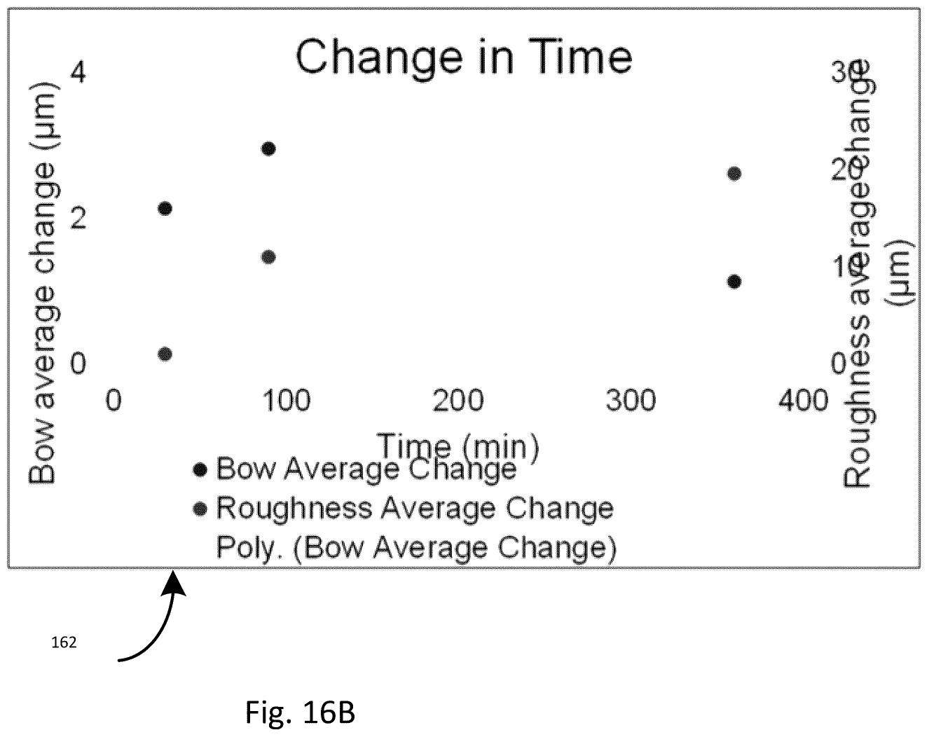

FIG. 16A is a graph 160 of the effect of bow average from the change in temperature during the pressing process for a sample metal wafer. FIG. 16B is a graph 162 of the effect of time (duration) on the bow average for a sample wafer. FIGS. 16A-B demonstrate the advantageous control of the bow average in the metal wafer 24 as a function of altering the predetermined temperature and predetermined duration of time.

It can thus be seen that the present invention also provides a method for producing a flattened metallic wafer substrate utilizing the system 10 in FIG. 1. The method starts with placing a second semiconductor wafer 22 on a bottom pressure tool plate 14, the bottom pressure tool plate 14 in physical contact with a second pressure application device 18. Then placing a metallic wafer 24 on the second semiconductor wafer 22 and placing a first semiconductor wafer 20 on the metallic wafer 24, the first semiconductor wafer 20 in physical contact with a top pressure tool plate 12, and the top pressure tool plate 12 in physical contact with a first pressure application device 16.

The method continues with applying a predetermined amount of pressure for a predetermined duration on the metallic wafer 24 from the top pressure tool plate 12 and bottom pressure tool plate 14 respectively from the first pressure application device 16 and second pressure application device 14, which thereby further applies pressure to the first semiconductor wafer 20 and second semiconductor water 22 respectively. The method then includes the step of flattening and/or smoothing the metallic wafer 24.

The method can further including heating, at least, the metallic wafer 24 with a heating device 26. The heating of the metallic wafer 24 can occur within a predetermined range of temperature between 150° C. to 400° C. Further, the predetermined amount of pressure can be between 1500 psi to 2000 psi.

Furthermore, placing the metallic wafer 24 can be done by depositing the metallic wafer 24 on the second semiconductor wafer 22. And the method can further include depositing a SiO₂ layer on the metallic wafer 24. Additionally, the method can include purposefully reducing roughness on the metallic wafer 24 to a predetermined level, with the reducing roughness occurring from the predetermined duration of pressure, such as applying the predetermined amount of pressure in a duration between 30 minutes to 90 minutes.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A system for producing a metallic wafer substrate, comprising:
a top pressure tool plate;
a bottom pressure tool plate;
a first pressure application device in physical contact with the top pressure tool plate;
a second pressure application device in physical contact with the bottom pressure tool plate;
a first semiconductor wafer in selective contact with the top pressure tool plate;
a second semiconductor wafer in selective contact with the bottom pressure tool plate; and
a metallic wafer selectively held between the first semiconductor wafer and second semiconductor wafer,
wherein a predetermined amount of pressure is applied, for a predetermined duration, to the top pressure tool plate and bottom pressure tool plate respectively from the first pressure application device and second pressure application device, thereby further applying pressure to the first semiconductor wafer and second semiconductor water respectively, to thereby flatten the metallic wafer.

2. The system of claim 1, further including a heating device.

3. The system of claim 2, wherein the heating device selectively applies a predetermined temperature to the system.

4. The system of claim 1, wherein the first semiconductor wafer and second semiconductor wafer include Si.

5. The system of claim 1, wherein the metallic wafer is deposited on the first semiconductor wafer, and the second semiconductor wafer is deposited on the metallic wafer.

6. The system of claim 1, further including a SiO₂ layer on the metallic wafer.

7. The system of claim 1, wherein the predetermined duration of pressure reduces roughness on the metallic wafer to a predetermined level.

8. The system of claim 1, wherein the metallic wafer is comprised of one or more of the group of: Mo, W, Cu, Al, and Ti.

9. The system of claim 3, where the predetermined temperature is in a range of 150° C. to 400° C.

10. A method for producing a flattened metallic wafer substrate, comprising:
placing a second semiconductor wafer on a bottom pressure tool plate, the bottom pressure tool plate in physical contact with a second pressure application device;
placing a metallic wafer on the second semiconductor wafer;
placing a first semiconductor wafer on the metallic wafer, the first semiconductor wafer in physical contact with a top pressure tool plate, and the top pressure tool plate in physical contact with a first pressure application device;
applying a predetermined amount of pressure for a predetermined duration on the metallic wafer from the top pressure tool plate and bottom pressure tool plate respectively from the first pressure application device and second pressure application device, thereby further applying pressure to the first semiconductor wafer and second semiconductor water respectively; and
flattening the metallic wafer.

11. The method of claim 10, further including heating, at least, the metallic wafer.

12. The method of claim 11, wherein heating the metallic wafer occurs within a predetermined range of temperature between 150° C. to 400° C.

13. The method of claim 10, wherein the predetermined amount of pressure is between 1500 psi to 2000 psi.

14. The method of claim 10, wherein placing the metallic wafer is depositing the metallic wafer on the second semiconductor wafer.

15. The method of claim 10, further including depositing a SiO₂ layer on the metallic wafer.

16. The method of claim 10, further comprising reducing roughness on the metallic wafer to a predetermined level, the reducing roughness occurring from the predetermined duration of pressure.

17. The method of claim 10, further including constructing the metallic wafer from one or more of the group of: Mo, W, Cu, Al, and Ti.

18. The method of claim 10, wherein applying a predetermined amount of pressure for a predetermined duration is applying the predetermined amount of pressure in a duration between 30 minutes to 90 minutes.

19. A system for producing a flattened metallic wafer substrate, comprising:
a top pressure tool plate;
a bottom pressure tool plate;
a first pressure means for applying pressure to the top pressure tool plate;
a second pressure means for applying to the bottom pressure tool plate;
a first semiconductor wafer in selective contact with the top pressure tool plate;
a second semiconductor wafer in selective contact with the bottom pressure tool plate; and
a metallic wafer selectively held between the first semiconductor wafer and second semiconductor wafer,
wherein a predetermined amount of pressure is applied, for a predetermined duration, to the top pressure tool plate and bottom pressure tool plate respectively from the first pressure means and second pressure means to flatten the metallic wafer.

20. The system of claim 19, further including a heating means for heating the metallic wafer.
